(19) United States
(12) Patent Application Publication
(10) Pub. No.: US 2015/0249171 A1
(43) Pub. Date: Sep. 3, 2015

(54) METHOD OF MAKING PHOTOVOLTAIC DEVICE COMPRISING I-III-VI2 COMPOUND ABSORBER HAVING TAILORED ATOMIC DISTRIBUTION

(71) Applicant: TSMC Solar Ltd., Taichung City (TW)

(72) Inventor: Chien-Yao HUANG, New Taipei City (TW)

(73) Assignee: TSMC Solar Ltd., Taichung City (TW)

(21) Appl. No.: 14/192,969

(22) Filed: Feb. 28, 2014

(51) Int. Cl. H01L 31/032; H01L 31/0224; H01L 31/18

(52) U.S. Cl. CPC H01L 31/0322; H01L 31/1864; H01L 31/022475

(57) ABSTRACT

A method of forming an absorber layer of a photovoltaic device includes forming a metal precursor layer above a substrate, and depositing a sulfur-containing precursor onto the metal precursor layer. The method further includes depositing a selenium-containing precursor onto the metal precursor layer after the step of depositing a sulfur-containing precursor.

### FIELD

The disclosure relates to photovoltaic devices generally, and more particularly relates to a method for making a photovoltaic device comprising a I-III-VI₂ compound as an absorber, and the resulting photovoltaic device.

### BACKGROUND

Photovoltaic devices (also referred to as solar cells) absorb sun light and convert light energy into electricity. Photovoltaic devices and manufacturing methods therefore are continually evolving to provide higher conversion efficiency with thinner designs.

Thin film solar cells are based on one or more layers of thin films of photovoltaic materials deposited on a substrate. The film thickness of the photovoltaic materials ranges from several nanometers to tens of micrometers. Examples of such photovoltaic materials include cadmium telluride (CdTe), copper indium gallium selenide (CIGS) and amorphous silicon (α-Si). These materials function as light absorbers. A photovoltaic device can further comprise other thin films such as a buffer layer, a back contact layer, and a front contact layer.

### BRIEF DESCRIPTION OF THE DRAWINGS

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like reference numerals denote like features throughout specification and drawings.

FIGS. 1A-1B are cross-sectional views of a portion of an exemplary photovoltaic device during fabrication, in accordance with some embodiments.

FIG. 2A is a flow chart diagram illustrating a method of fabricating an exemplary photovoltaic device in accordance with some embodiments.

FIG. 2B is a flow chart diagram illustrating a method of forming an absorber layer of an exemplary photovoltaic device in accordance with some embodiments.

FIG. 3 shows a process for forming an absorber layer comprising selenization followed by sulfuration in one embodiment.

FIGS. 4A-4B illustrate resulting profiles of sulfur and Group III atoms distributed across the absorber layer after a process of FIG. 3 is used.

FIG. 5 illustrates a process for forming an absorber layer having tailored atomic distribution in accordance with some embodiments.

FIGS. 6A-6B illustrate resulting profiles of sulfur and Group III atoms distributed across the absorber layer after a process of FIG. 5 is used.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

In a thin-film photovoltaic device, a back contact layer is deposited over a substrate. An absorber layer is deposited over the back contact layer. A buffer layer comprising a suitable buffer material is disposed above an absorber layer. The buffer layer and the absorber layer, which both comprise a semiconductor material, provide a p-n or n-p junction. When the absorber layer absorbs sun light, electric current can be generated at the p-n or n-p junction.

Copper indium gallium selenide and/or sulfide (CIGS) is a commonly used absorber layer in thin film solar cells. CIGS thin film solar cells have achieved excellent conversion efficiency (>20%) in laboratory environments. Most conventional CIGS deposition is done by one of two techniques: co-evaporation or selenization. Co-evaporation involves simultaneously evaporating copper, indium, gallium and selenium. The different melting points of the four elements make controlling the formation of a stoichiometric compound on a large substrate very difficult. Additionally, film adhesion is very poor when using co-evaporation. Selenization involves a two-step process. First, a copper, gallium, and indium precursor is sputtered on to a substrate. Second, selenization occurs by a reaction of the precursor with H₂Se/H₂S at 500° C. or above.

The inventor has found that sulfur accumulated in the interface between the absorber layer and the back contact layer deteriorates the electric back contact, and further decreases the fill factor and reliability of photovoltaic devices. Non-uniformity of other ingredients of the absorber layer due to relatively poor inter-diffusion can also decrease the performance of photovoltaic devices.

The present disclosure provides a method of forming an absorber layer of a photovoltaic device, a method for fabricating a photovoltaic device, and a resulting photovoltaic device. The absorber layer comprises at least one “I-III-VI₂” compound comprising a Group I element, a Group III element, and a Group VI element. The absorber layer has tailored atomic distributions, particularly of the Group III elements (e.g., Ga and Tl) and the Group IV elements such as sulfur.

Unless expressly indicated otherwise, references to a “front side” of a substrate made in this disclosure will be understood to encompass the side on which a light absorber layer will be deposited. References to a “back side” of the substrate made below will be understood to encompass the other side opposite to the side where the light absorber layer will be deposited. References to a “substrate” will be understood to encompass a substrate with or without a back contact layer, for example, a metal coated glass substrate. When the substrate is a metal coated glass, the “back side” is the glass layer while the “front side” is the metal layer deposited over the glass layer as the back contact layer.

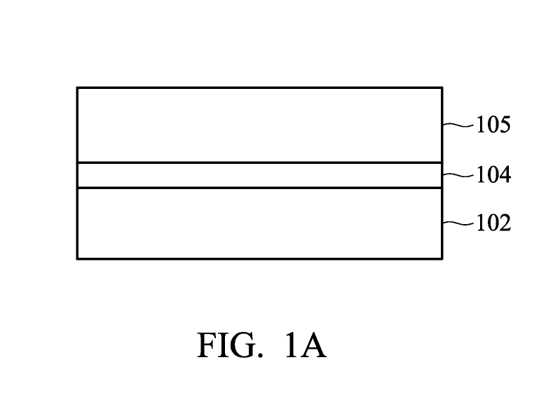

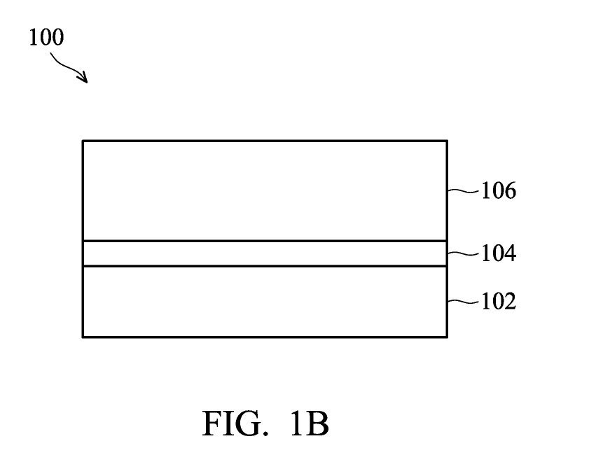

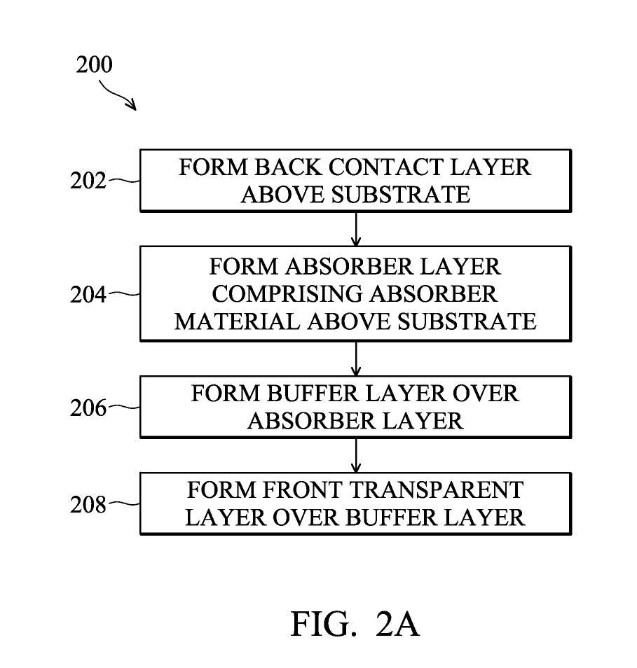

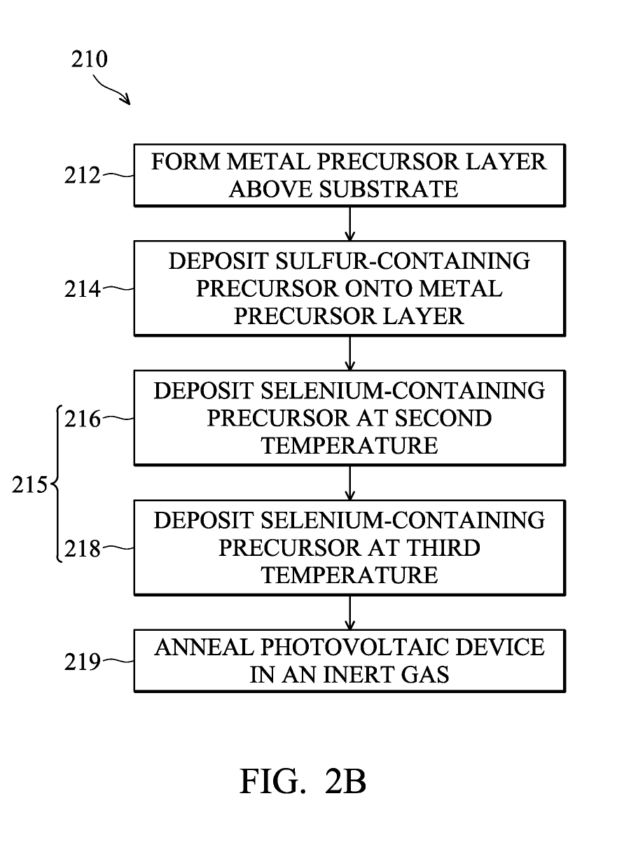

In FIGS. 1A-1B, like items are indicated by like reference numerals, and for brevity, descriptions of the structure, provided above with reference to the previous figure, are not repeated. The methods are described in FIGS. 2A-2B with reference to the exemplary structure described in FIGS. 1A-1B. FIGS. 1A-1B show a solar cell at two different stages in the fabrication process. As shown in FIG. 1A, a substrate 102 is provided, and a back contact layer 104 and a metal precursor layer 105 are formed above the substrate. As shown in FIG. 2B, the metal precursor 105 is used to form absorber layer 106.

FIG. 2A illustrates an exemplary method 200 of fabricating an exemplary photovoltaic device 100 in accordance with some embodiments. FIG. 2B illustrates an exemplary method 210 of forming absorber layer 106 of an exemplary photovoltaic device 100 in accordance with some embodiments.

At step 202 of FIG. 2A, the back contact layer 104 is formed above a substrate 102. The resulting structure of a portion of a photovoltaic device 100 is illustrated in FIG. 1A.

Substrate 102 and back contact layer 104 are made of any material suitable for such layers in thin film photovoltaic devices. Examples of materials suitable for use in substrate 102 include but are not limited to glass (such as soda lime glass), polymer (e.g., polyimide) film and metal foils (such as stainless steel). The film thickness of substrate 102 is in any suitable range, for example, in the range of 0.1 mm to 5 mm in some embodiments.

In some embodiments, substrate 102 can comprise two or more layers. For example, substrate 102 can include a first layer 101 (not shown) comprising glass, and a second layer 103 (not shown) disposed over the first layer and comprising silicon dioxide, which can be used to block possible diffusion of sodium in glass. In some embodiments, layer 101 comprises soda lime glass or other glass, which can tolerate a process at a temperature higher than 600° C. In some embodiments, layer 103 comprises silicon oxide having a formula SiOₓ, where x ranges from 0.3 to 2.

Examples of suitable materials for back contact layer 104 include, but are not limited to molybdenum (Mo), copper, nickel, or any other metals or conductive material. Back contact layer 104 can be selected based on the type of thin film photovoltaic device. For example, back contact layer 104 is Mo in some embodiments. The thickness of back contact layer 104 is on the order of nanometers or micrometers, for example, in the range from 100 nm to 20 microns. The thickness of back contact layer 104 is in the range of from 200 nm to 10 microns in some embodiments. Back contact layer 104 can be also etched to form a pattern.

At step 204 of FIG. 2A, an absorber layer 106 comprising an absorber material is formed above back contact layer 104 and above substrate 102. Step 204 can comprises a step of forming a metal precursor layer 105 (as shown in FIG. 1A), and other subsequent steps as described in FIG. 2B. After absorber layer 106 is formed, the resulting structure of photovoltaic device 100 is as illustrated in FIG. 1B.

Absorber layer 106 can be a p-type or n-type semiconductor material. Examples of materials suitable for absorber layer 106 include but are not limited to copper indium gallium selenide (CIGS), cadmium telluride (CdTe), and amorphous silicon (α-Si). In some embodiments, absorber layer 106 comprises a I-III-VI₂ compound. For example, absorber layer 106 can comprise material of a chalcopyrite family (e.g., CIGS) or kesterite family (e.g., BZnSnS and CZTS). In some embodiments, absorber layer 106 is a semiconductor comprising copper, indium, gallium and selenium, such as CuInₓGa₍₁₋ₓ₎Se₂, where x is in the range of from 0 to 1. Selenium can be also replaced with sulfur. In some embodiments, absorber layer 106 is a p-type semiconductor. Absorber layer 106 has a thickness on the order of nanometers or micrometers, for example, 0.5 microns to 10 microns. In some embodiments, the thickness of absorber layer 106 is in the range of 500 nm to 2 microns.

Unless expressly indicated otherwise, references to a “I-III-VI₂ compound” made in this disclosure will be understood to encompass a material selected from a Group I element, a Group III element, an alloy or any combination thereof. The Group I element can be selected from Cu or Ag. The Group III element can be selected from Al, Ga, In or Tl. The Group VI element can be sulfur or selenium (Se). In this disclosure, Group I, Group III, and Group VI refer to Group IB, Group IIIA and Group VIA, respectively, in the “traditional” periodic table. Based on the modern numbering system recommended by the International Union of Pure and Applied Chemistry (IUPAC), Group I, Group III, and Group VI refer to Group 11, Group 13 and Group 16, respectively.

Unless expressly indicated otherwise, references to “CIGS” made in this disclosure will be understood to encompass a material comprising copper indium gallium sulfide and/or selenide, for example, copper indium gallium selenide, copper indium gallium sulfide, and copper indium gallium sulfide/selenide. A selenide material may comprise sulfide or selenide can be completely replaced with sulfide.

Absorber layer 106 can be formed according to methods such as sputtering, chemical vapor deposition, printing, electrodeposition or the like. For example, in some embodiments, CIGS is formed by first sputtering a metal film comprising copper, indium and gallium at a specific ratio, followed by a selenization process of introducing selenium or selenium containing chemicals in gas state into the metal film. In some embodiments, the selenium is deposited by evaporation physical vapor deposition (PVD).

FIG. 2B illustrates a method 210 of forming an absorber layer 106 in accordance with some embodiments.

At step 212, a metal precursor layer 105 is formed above substrate 102. Metal precursor layer 105 can comprise at least one material selected from the group consisting of a Group I element such as Cu and Ag, a Group III element such as Al, Ga, In and Tl, and any alloy or combination thereof. Metal precursor layer 105 can comprise selenium (Se) in some embodiments.

Metal precursor layer 105 can be formed using any suitable method. For example, metal precursors can be formed through sputtering method from at least one sputtering source in a vacuum chamber. Sputtering sources can be, for example, a magnetron, an ion beam source, a RF generator, or any suitable sputtering source configured to deposit a respective ingredient for absorber layer 106. Each sputtering source can include at least one sputtering target. A suitable sputtering gas such as argon can be used. Other possible sputtering gases include krypton, xenon, neon, and similarly inert gases.

In some embodiments, more than two sputtering sources can be used to form the metal precursors. For example, a first sputtering source can be used to deposit atoms of a first ingredient (e.g., Cu, or Cu and Ga) for absorber layer 106. A second sputtering source can be used to deposit atoms of a second ingredient (e.g. In). The ingredients can be co-deposited or deposited at different layers at a predetermined ratio.

At step 212, metal precursor layer 105 can be in one or more than two layers. For example all the elements including both Group I and Group III elements can be co-deposited together. In some embodiments, two or three layers can be formed. For example, a bottom layer comprising Cu and Ga in any suitable atomic ratio (e.g., Cu/Ga in the range of from 70:30 to 60:40) is first deposited. A second layer comprising Cu and Ga in a different atomic ratio (e.g., Cu/Ga in the range of from 85:15 to 75:25) is then formed. A top layer comprising indium (In) can be subsequently deposited. Each layer can be at any thickness, for example, in the range from 100 nm to 900 nm. In some embodiments, a certain amount of selenium can be deposited in the course of step 212. For example, a thin layer of selenium at any thickness (e.g., 100-200 nm) can be formed as a middle layer when depositing Group I and Group III elements.

In some embodiments, during the sputtering process, indium can be doped with alkaline elements such as sodium (Na) or potassium (K). Doping an indium sputtering target with sodium may avoid or minimize an alkali-silicate layer in the solar cell.

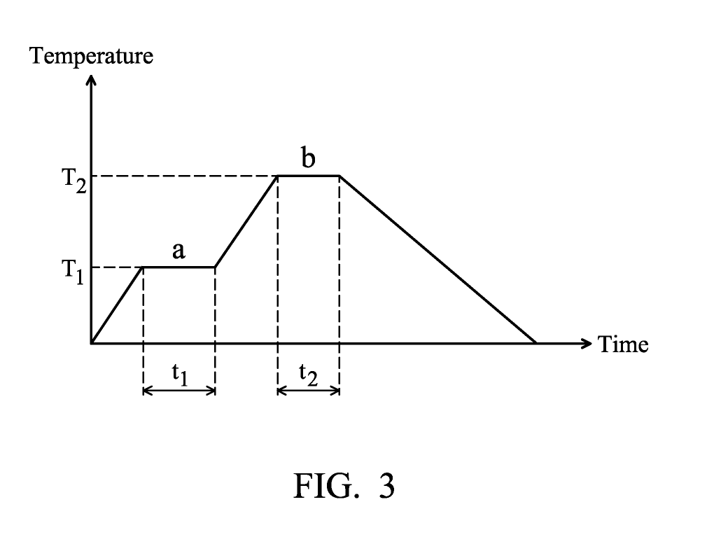

After metal precursor 105 is formed, several methods can be used to form absorber layer 106. In one embodiment, as shown in FIG. 3, a process comprises selenization followed by sulfuration. In FIG. 3, selenization occurs at a temperature (T₁) in the range of from 350° C. to 450° C. for a time of period (t₁). The temperature is then subsequently raised to T₂, for example, in the range of from 500° C. to 550° C., at which sulfuration is carried out for a time of period (t₂). Sulfur can replace selenium in the process of sulfuration following selenization. Absorber layer 106 comprising a I-III-VI2 compound can be formed using the process of FIG. 3.

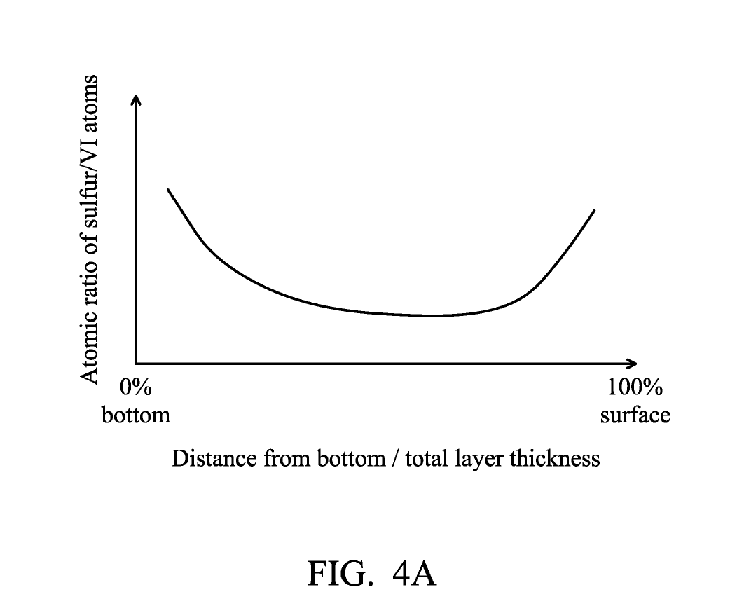

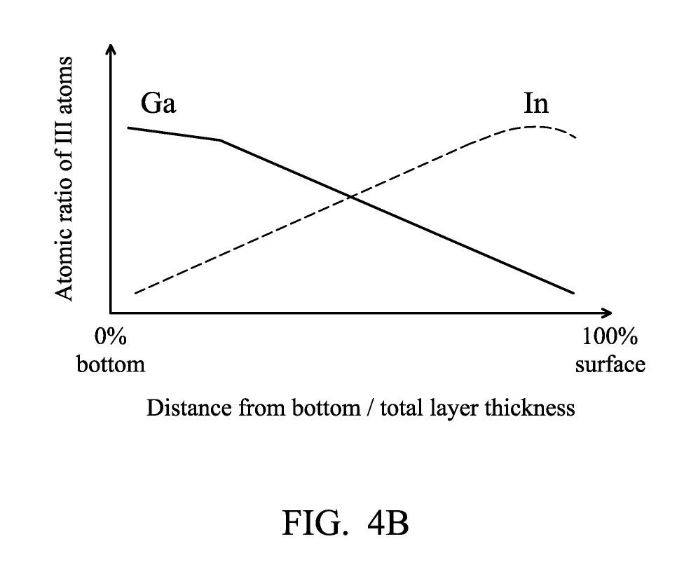

However, this process of FIG. 3 may result in accumulation of sulfur in the interface between absorber layer 106 and the back contact layer 104. An exemplary profile of sulfur is shown in FIG. 4B. The concentration of sulfur at the bottom of absorber layer 106 (i.e the interface between absorber layer 106 and back contact layer 104) is much higher than that in the middle portion of absorber layer 106. More grain boundaries near the interface attract more sulfur to the bottom of absorber layer 106. The process may also result in uncontrollable gradient band gap from the Group III element. FIG. 4B illustrates exemplary profiles of Ga and In. The Group III elements have different thermal diffusion capability. For example, Ga has lower thermal diffusion compared to In. Therefore, the process of FIG. 3 results in non-uniform distribution of both Ga and In in absorber layer 106.

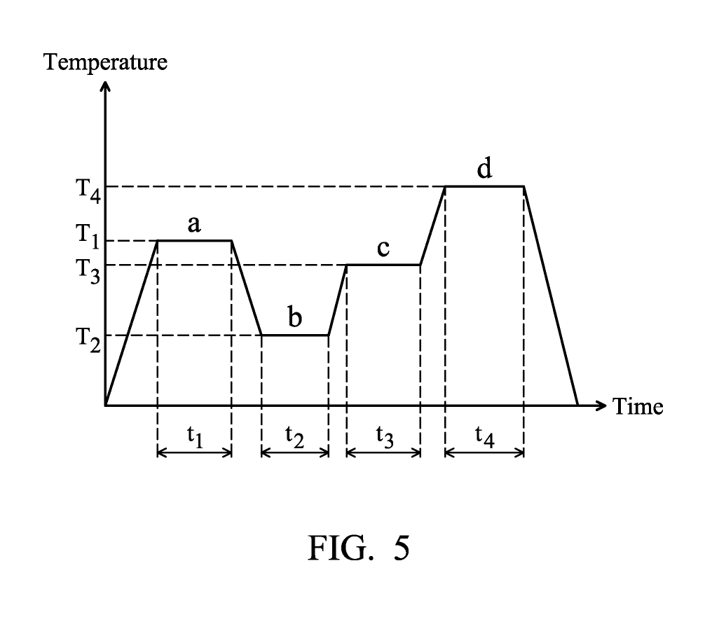

In some other embodiments, as shown in FIG. 2B, different processes can be used to mitigate or eliminate the accumulation of sulfur. For the illustration purpose, FIG. 5 illustrates an exemplary process for forming an absorber layer 106 having tailored atomic distribution in accordance with some embodiments.

At step 214, a sulfur-containing precursor is deposited onto the metal precursor layer 105. Examples of a sulfur-containing precursor include but are not limited to hydrogen sulfur or elemental sulfur vapor. As shown in FIG. 5, the sulfur-containing precursor is deposited at a first temperature (T₁), which can be in the range of from 300° C. to 550° C. (e.g., from 350° C. to 450° C.). The time length (t₁ in FIG. 5) for depositing sulfur-containing precursor can be in the range of from 0.1 to 300 minutes.

At step 215, a selenium-containing precursor is deposited onto the metal precursor layer 105 after the step of depositing a sulfur-containing precursor. In some embodiments, a selenium-containing precursor is deposited onto the metal precursor layer 105 at a temperature lower than a first temperature at which the sulfur-containing precursor is deposited. In some embodiments, selenium can be deposit using an evaporation source comprising any suitable selenium containing precursor. Evaporation source can be configured to produce a vapor of such suitable selenium containing precursor. The vapor can condense upon metal precursor layer 105. In some embodiments, the vapor can be ionized, for example using an ionization discharger, prior to condensation.

In some embodiments, as shown in FIGS. 2B and 5, the step of depositing a selenium-containing precursor onto the metal precursor layer comprises two steps: step 216 and step 218. At step 216, a selenium-containing precursor is deposited at a second temperature (T₂). At step 218, a same or different selenium-containing precursor is deposited at a third temperature (T₃). T₂ and T₃ are different from each other. In some embodiments, T₁ is higher than T₂ and T₂ is lower than T₃. T₃ can be higher or lower than T₁. The selenium-containing precursor can comprise hydrogen selenium or elemental selenium vapor. T₂ can be in the range of from 25° C. to 350° C. (e.g., from 250° C. to 350° C.). T₃ can be in the range of from 400° C. to 600° C. (e.g., 400° C. to 500° C.). In each depositing step, the time length (t₂ or t₃) for depositing selenium precursor at each temperature can be in the range of from 0.1 to 300 minutes, respectively.

At step 219, in some embodiments, method 210 further comprises annealing the photovoltaic device in an inert gas after step 215. Annealing can be performed in an inert gas comprising nitrogen, argon or any other inert gas, or combinations thereof, at a temperature (T₄) in the range of from 500° C. to 800° C. (e.g., from 500° C. to 600° C.). The annealing time length (t₄) can be in the range from 0.1 to 300 minutes.

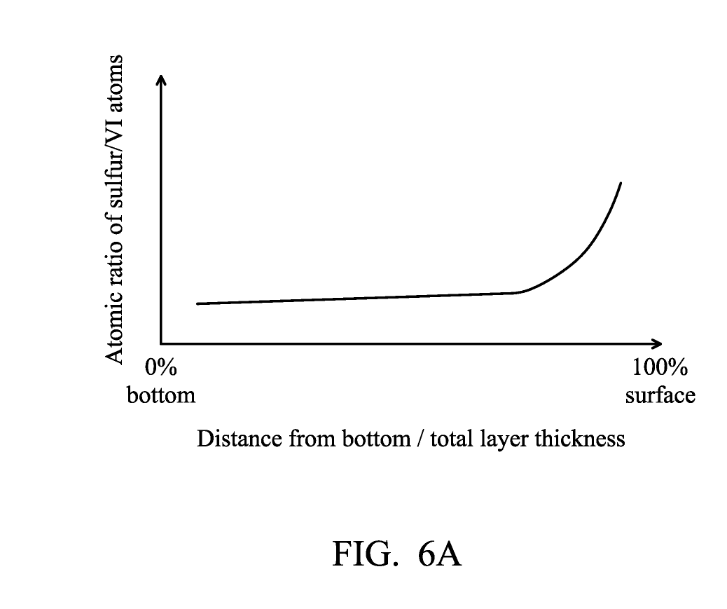

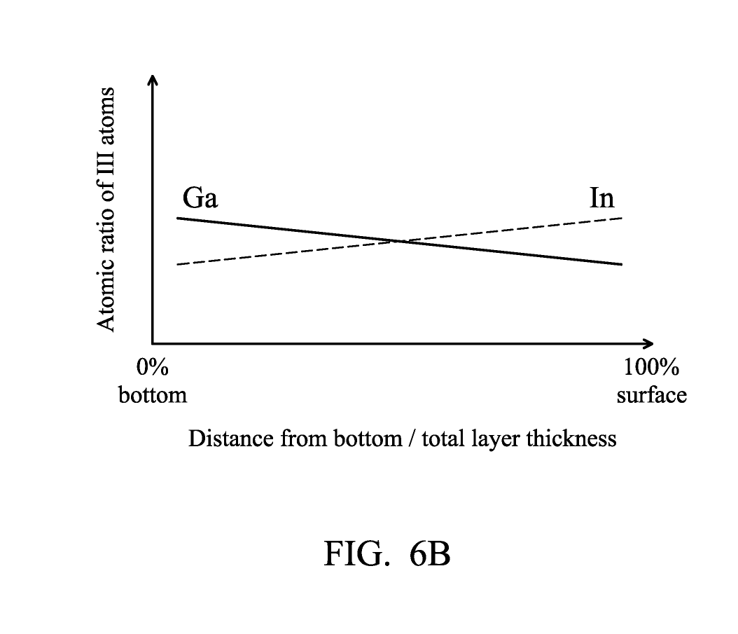

FIGS. 6A-6B illustrate resulting profiles of sulfur and Group III atoms distributed across absorber layer 106 after a process of FIG. 5 is used. As shown in FIG. 6A, sulfur first reacts with Group I or Group III element in metal precursor layer 105. The resulting compound may be more stable than the counterparts containing selenium. So sulfur atoms do not diffuse into the bottom of absorber layer 106 (i.e. the interface between absorber layer 106 and back contact layer 104). In addition, step 219 of annealing at high temperature provides more uniform distribution of the Group III atoms such as Ga and In.

In some embodiments, the bottom surface of absorber layer 106 is essentially free of sulfur. The atomic ratio of sulfur to the amount of selenium and sulfur is in the range of from 0.1 to 1.0 on an upper surface of absorber layer 106. The atomic ratio of sulfur to the amount of selenium and sulfur is in the range of from 0 to 0.05 at the bottom surface of absorber layer 106. In some embodiments, absorber layer 106 comprises Ga, and the ratio of Ga at the upper surface to Ga at the bottom surface is in the range from 25% to 100%.

The method described in the present disclosure can be used to control sulfur distribution in absorber layer 106, particularly prevent sulfur accumulated in the interface between absorber layer 106 and back contact layer 104. The methods can be also used to control distribution profiles of metal elements of a I-III-VI₂ compound in absorber layer 106 to provide uniformity. The resulting absorber layer 106 can provide improved fill factor, reliability and overall performance of resulting photovoltaic devices.

Referring back to FIG. 2A, at step 206, a buffer layer 108 (not shown) comprising a buffer material is formed over absorber layer 106. Examples of a buffer material include but are not limited to ZnS, CdS, CdSe, ZnO, ZnSe, ZnIn₂Se₄, CuGaS₂, In₂S₃, MgO and Zn_{0.8} Mg_{0.2} O in some embodiments. Such a buffer material can be an n-type semiconductor and absorber layer 106 comprises p-type GIGS in some embodiments. The thickness of buffer layer 108 is on the order of nanometers, for example, in the range of from 5 nm to 100 nm in some embodiments.

Formation of buffer layer 108 can be achieved through a suitable process such as sputtering, chemical vapor deposition, and a hydrothermal reaction or chemical bath deposition (CBD) in a solution. For example, buffer layer 108 comprising ZnS can be formed in an aqueous solution comprising ZnSO₄, ammonia and thiourea at 80° C. A suitable solution comprises 0.16M of ZnSO_{4, 7.5}M of ammonia, and 0.6 M of thiourea in some embodiments.

At step 208, a front contact or front transparent layer 110 (not shown) is formed over buffer layer 108. As a part of “window layer,” front transparent layer 110 can also comprise two layers, for example, including an intrinsic ZnO (i-ZnO) layer and a front contact layer comprising transparent conductive oxide (TCO) or any other transparent conductive coating in some embodiments. In some embodiments, undoped i-ZnO is used to prevent short circuiting in the photovoltaic device 100. In thin film solar cells, film thickness of absorber layer 106 can range from several nanometers to tens of micrometers. If front contact layer 114 and back contact layer 104 are unintentionally connected because of defects in the thin films, an unwanted short circuit (shunt path) will be provided. Such phenomenon decreases performance of the photovoltaic devices, and can cause the devices to fail to operate within specifications. The loss of efficiency due to the power dissipation resulting from the shunt paths can be up to 100%. In some embodiments, undoped i-ZnO is thus provided in between the front- and the back contact layers to prevent short circuiting, for example, above buffer layer 108, between the buffer layer 108 and the front contact layer. Intrinsic ZnO having high electrical resistance can mitigate the shunt current and reduce formation of the shunt paths.

Front contact layer 110 is used in a photovoltaic (PV) device with dual functions: transmitting light to an absorber layer while also serving as a front contact to transport photo-generated electrical charges away to form output current. Transparent conductive oxides (TCOs) are used as front contacts in some embodiments. In some other embodiments, front contact layer is made of a transparent conductive coating comprising nanoparticles such as metal nanoparticles or nanotubes such as carbon nanotubes (CNT). Both high electrical conductivity and high optical transmittance of the transparent conductive layer are desirable to improve photovoltaic efficiency.

Examples of a suitable material for the front contact layer 110 include but are not limited to transparent conductive oxides such as indium tin oxide (ITO), fluorine-doped tin oxide (FTO), aluminum-doped zinc oxide (AZO), gallium doped ZnO (GZO), alumina and gallium co-doped ZnO (AGZO), boron doped ZnO (BZO), and any combination thereof. A suitable material can also be a composite material comprising at least one of the transparent conductive oxide (TCO) and another conductive material, which does not significantly decrease electrical conductivity or optical transparency of front contact layer. The thickness of front contact layer 110 is in the order of nanometers or microns, for example in the range of from 0.3 nm to 2.5 μm in some embodiments.

An anti-reflection layer can be also is formed over front transparent layer 110 in some embodiments. Examples of a suitable material for anti-reflection layer 116 include but are not limited to SiO₂ and MgF₂.

In another aspect, the present disclosure also provides a method of fabricating a photovoltaic device 100. The method comprises forming back contact layer 104 above substrate 102, and forming absorber layer 106 comprising an absorber material above the substrate 102. In some embodiments, the step of forming absorber layer 106 comprises the steps described above.

The present disclosure also provides a photovoltaic device comprising substrate 102, back contact layer 104 disposed above substrate 102, and absorber layer 106 comprising an absorber material disposed above back contact layer 104. Such layers are described above. In some embodiments, a bottom surface of absorber layer 106 is essentially free of sulfur. The atomic ratio of sulfur to the amount of selenium and sulfur is in the range of from 0.1 to 1.0 on an upper surface of absorber layer 106. In some embodiments, absorber layer 106 comprises Ga, and the ratio of Ga at the upper surface to Ga at the bottom surface is in the range from 25% to 100%. Photovoltaic device 100 can further comprise buffer layer 108 disposed over absorber layer 106. Photovoltaic device 100 can further comprise a front transparent layer 110 disposed above buffer layer 108 and an anti-reflection layer 116 disposed above front transparent layer 110.

The present disclosure provides a method of forming an absorber layer of a photovoltaic device. The method comprises the following steps: forming a metal precursor layer above a substrate, depositing a sulfur-containing precursor onto the metal precursor layer, and depositing a selenium-containing precursor onto the metal precursor layer after the step of depositing a sulfur-containing precursor. In some embodiments, the metal precursor layer comprises a material selected from a Group I element, a Group III element, an alloy or any combination thereof. The Group I element can be selected from Cu or Ag. The Group III element can be selected from Al, Ga, In or Tl. In some embodiments, the metal precursor layer further comprises selenium (Se).

In some embodiments, in the step of depositing the sulfur-containing precursor onto the metal precursor layer, the sulfur-containing precursor comprises hydrogen sulfur or elemental sulfur vapor. The sulfur-containing precursor is deposited at a first temperature in the range of from 300° C. to 550° C. (e.g., from 350° C. to 450° C.). In some embodiments, a selenium-containing precursor is deposited onto the metal precursor layer at at least one temperature lower than a first temperature at which the sulfur-containing precursor is deposited. In some embodiments, the step of depositing a selenium-containing precursor onto the metal precursor layer comprises: depositing the selenium-containing precursor at a second temperature, and depositing the selenium-containing precursor at a third temperature different from the second temperature. The selenium-containing precursor can comprise hydrogen selenium or elemental selenium vapor. The second temperature can be in the range of from 25° C. to 350° C. (e.g., from 250° C. to 350° C.). The third temperature can be in the range of from 400° C. to 600° C. (e.g., 400° C. to 500° C.). The time length for depositing sulfur-containing precursor or selenium precursor at the first, the second or the third temperature can be in the range of from 0.1 to 300 minutes, respectively.

In some embodiments, the method further comprises annealing the photovoltaic device in an inert gas after the step of depositing the selenium-containing precursor onto the metal precursor layer Annealing can be performed in an inert gas comprising nitrogen or argon, at a temperature in the range of from 500° C. to 800° C. (e.g., from 500° C. to 600° C.). The annealing time length can be in the range from 0.1 to 300 minutes.

In another aspect, the present disclosure also provides a method of fabricating a photovoltaic device. The method comprises forming a back contact layer above a substrate, and forming an absorber layer comprising an absorber material above the substrate. In some embodiments, the step of forming an absorber layer comprises the steps described above. The step of forming an absorber layer can comprise forming a metal precursor layer above a substrate, depositing a sulfur-containing precursor onto the metal precursor layer, and depositing a selenium-containing precursor onto the metal precursor layer after the step of depositing a sulfur-containing precursor.

In some embodiments, the step of depositing a selenium-containing precursor onto the metal precursor layer comprises: depositing the selenium-containing precursor at a second temperature, and depositing the selenium-containing precursor at a third temperature different from the second temperature. The second temperature is lower than the first temperature and the second temperature is lower than the third temperature in some embodiments. In some embodiments, the first temperature is in the range of from 300° C. to 550° C. The second temperature is in the range of from 25° C. to 350° C. The third temperature is in the range of from 400° C. to 600° C.

In some embodiments, the step of forming an absorber layer above the substrate further comprises annealing the photovoltaic device in an inert gas after the step of depositing a selenium-containing precursor onto the metal precursor layer. Annealing can be performed in an inert gas comprising nitrogen or argon, and at a temperature in the range of from 500° C. to 800° C. in some embodiments.

The present disclosure also provides a photovoltaic device comprising a substrate, a back contact layer disposed above the substrate, and an absorber layer comprising an absorber material disposed above the back contact layer. In some embodiments, a bottom surface of the absorber layer is essentially free of sulfur. The atomic ratio of sulfur to the amount of selenium and sulfur is in the range of from 0.1 to 1.0 on an upper surface of the absorber layer. In some embodiments, the absorber layer comprises Ga, and the ratio of Ga at the upper surface to Ga at the bottom surface is in the range from 25% to 100%. The photovoltaic device can further comprise a buffer layer disposed over the absorber layer, and a front transparent layer disposed over the buffer layer.

Although the subject matter has been described in terms of exemplary embodiments, it is not limited thereto. Rather, the appended claims should be construed broadly, to include other variants and embodiments, which may be made by those skilled in the art.

1. A method of forming an absorber layer of a photovoltaic device, comprising
forming a metal precursor layer above a substrate;
depositing a sulfur-containing precursor onto the metal precursor layer; and
depositing a selenium-containing precursor onto the metal precursor layer after the step of depositing a sulfur-containing precursor.

2. The method of claim 1, wherein
the metal precursor layer comprises a material selected from the group consisting of a Group I element, a Group III element, an alloy or any combination thereof.

3. The method of claim 2, wherein
the Group I element is selected from a group consisting of Cu and Ag.

4. The method of claim 2, wherein
the Group III element is selected from a group consisting of Al, Ga, In and Tl.

5. The method of claim 2, wherein
the metal precursor layer further comprises selenium (Se).

6. The method of claim 1, wherein in the step of depositing the sulfur-containing precursor onto the metal precursor layer,
the sulfur-containing precursor comprises hydrogen sulfur or elemental sulfur vapor; and
the sulfur-containing precursor is deposited at a first temperature in the range of from 300° C. to 550° C.

7. The method of claim 1, wherein a selenium-containing precursor is deposited onto the metal precursor layer at at least one temperature lower than a first temperature at which the sulfur-containing precursor is deposited.

8. The method of claim 7, wherein the step of depositing a selenium-containing precursor onto the metal precursor layer comprises:
depositing the selenium-containing precursor at a second temperature; and
depositing the selenium-containing precursor at a third temperature different from the second temperature.

9. The method of claim 8, wherein
the selenium-containing precursor comprises hydrogen selenium or elemental selenium vapor;
the second temperature is in the range of from 25° C. to 350° C.; and
the third temperature is in the range of from 400° C. to 600° C.

10. The method of claim 1, further comprising:
annealing the photovoltaic device in an inert gas after the step of depositing the selenium-containing precursor onto the metal precursor layer.

11. The method of claim 10, wherein annealing is performed in an inert gas comprising nitrogen or argon, at a temperature in the range of from 500° C. to 800° C.

12. A method of fabricating a photovoltaic device, comprising forming a back contact layer above a substrate; and
forming an absorber layer comprising an absorber material above the substrate, wherein the step of forming an absorber layer comprises:
forming a metal precursor layer above a substrate;
depositing a sulfur-containing precursor onto the metal precursor layer; and
depositing a selenium-containing precursor onto the metal precursor layer after the step of depositing a sulfur-containing precursor.

13. A method of claim 12, wherein the step of depositing a selenium-containing precursor onto the metal precursor layer comprises:
depositing the selenium-containing precursor at a second temperature; and
depositing the selenium-containing precursor at a third temperature different from the second temperature.

14. The method of claim 13, wherein:
the second temperature is lower than the first temperature, and lower than the third temperature.

15. The method of claim 13, wherein
the first temperature is in the range of from 300° C. to 550° C.;
the second temperature is in the range of from 25° C. to 350° C.; and
the third temperature is in the range of from 400° C. to 600° C.

16. The method of claim 12, wherein the step of forming an absorber layer above the substrate further comprises
annealing the photovoltaic device in an inert gas after the step of depositing a selenium-containing precursor onto the metal precursor layer.

17. The method of claim 16, wherein annealing is performed in an inert gas comprising nitrogen or argon, and at a temperature in the range of from 500° C. to 800° C.

18-20. (canceled)

21. The method of claim 12, wherein a bottom surface of the absorber layer is essentially free of sulfur, and the atomic ratio of sulfur to the amount of selenium and sulfur is in the range of from 0.1 to 1.0 on an upper surface of the absorber layer.

22. The method of claim 12, wherein
the absorber layer comprises Ga, and the ratio of Ga at the upper surface to Ga at the bottom surface is in the range from 25% to 100%.

23. The method of claim 12, further comprising:
forming a buffer layer over the absorber layer; and
forming a front transparent layer over the buffer layer.
